(19) United States
(12) Patent Application Publication
(10) Pub. No.: US 2004/0077310 A1
(43) Pub. Date: Apr. 22, 2004

(54) Hybrid networking system

(76) Inventor: David Levy, Karmiel (IL)

Correspondence Address: BROWDY AND NEIMARK, P.L.L.C., 624 NINTH STREET, NW, SUITE 300, WASHINGTON, DC, 20001-5303, US

(21) Appl. No.: 10/640,382

(22) Filed: Aug. 14, 2003

Related U.S. Application Data
(60) Provisional application No. 60/404,576, filed on Aug. 14, 2002.

(51) Int. Cl. H03K 7/06; H04Q 7/20; H04M 1/00; H04H 1/00

(52) U.S. Cl. 455/7; 455/445; 455/561; 375/260; 375/271; 455/3.02

(57) ABSTRACT

A method for transmitting data signals between nodes in a networking system having one or more signal splitters. The method comprises transmitting wired and wireless data signals between nodes at a same frequency at which the effective isolation of each signal splitter at that frequency is substantially less than the specified effective isolation of each splitter. The invention also provides a wired networking system comprising one or more signal splitters. Each node in the system is configured to transmit and receive wired and wireless data signals over the system at a same frequency at which the effective isolation of each splitter is less than the specified effective isolation of each splitter.

### FIELD OF THE INVENTION

This invention relates to networking systems for multi-media and data distribution.

### BACKGROUND OF THE INVENTION

The term “home networking” is used to refer to a system for in-house multimedia and data distribution among the nodes of a network located at a single installation. For example, the nodes of a home network may include video player, CD ROM, and several televisions and computer terminals located in different rooms. The network may be a wired system, in which case communication between the nodes occurs over a wired network that may be, for example, a phone line, a power line, or a coaxial cable. Alternatively, the network may be a wireless system in which case communication between the nodes uses a protocol such as 802.11a or HiperLan-2.

Wired systems, utilizing coax, phone lines, or power lines provide good throughput, but suffer from several drawbacks:

[symbol] Limited mobility. Portable multimedia devices, such as camcorders, cannot be utilized efficiently on a wired system.

[symbol] Removing echoes that appear in signals transmitted over a wired system sometimes requires a transceiver that is as complex as a wireless transceiver.

[symbol] Wired coaxial systems utilize coax signal splitters (referred to herein as “splitters”) which at the RF frequencies used for coaxial or cable transmission, the splitters are essentially “one way” devices that cannot provide connectivity between two nodes of the system connected to different output ports of the splitter. Therefore, wired systems that use RF frequencies do not permit the nodes to communicate with one another as is required for a fully connected network. Thus, these wired systems can only have a “tree” structure in which all nodes communicate only with the source. Wired systems cannot have a “mesh” structure in which nodes communicate with each other.

In order to allow communication between nodes of a wired network it is known transmit digital audio-visual (AV) signals between nodes in a wired home networking system using a frequency that is sufficiently high so as to allow transmission via a splitter in the isolation direction (i.e. from output to output). This relies on the fact the effective isolation within a cable signal splitter, at frequencies higher than the nominal, is much lower than the specified isolation, due to high capacitive coupling between the ports. The nominal frequency for cable installations is in the lower RF band (up to 860 MHz) and the nominal frequency for satellite installations is in the upper band (960 to 2400 MHz). Thus, transmission between nodes in a wired system may be carried out using a frequency substantially above 860 MHz in a cable installation, and substantially above 2,400 MHz in a satellite installation.

Wireless systems, on the other hand, such as those using the 802.11a or HiperLan2 standards, provide good coverage, high throughput, node to node connectivity and, of course, mobility. However, wireless systems also suffer from several drawbacks:

[symbol] Limited wireless range. The range is highly dependent on path, and decreases considerably between rooms separated by solid concrete walls or floors. Thus, in a typical house, there may be some locations that cannot be served by wireless network due to propagation problems. For example a basement located node, which might be blocked by concrete walls.

[symbol] Susceptibility to interference. Wireless systems utilize unlicensed RF bands that are also used by satellites and RADAR systems. Even though the spectrum is well arranged, and the RF output power is controlled to minimized interference, collocated wireless systems may cause mutual interference.

[symbol] Large area installations cannot be served entirely by wireless, because spectrum regulations limit the output power from a wireless transmitter. As a result, installations in which the distance between nodes is large cannot be fully covered with wireless service.

### SUMMARY OF THE INVENTION

The present invention provides a hybrid networking system in which digital AV signals may be transmitted between nodes over a wired subsystem and a wireless subsystem. By allowing both wired and wireless communication between nodes, the disadvantages of either mode of communication alone are substantially overcome. In accordance with the invention, the nodes are configured to transmit and receive wired and wireless data signals at the same frequency. The transmission frequency is one at which the effective isolation of each splitter in the system is substantially less than the specified effective isolation of the splitter. As shown below, use of the same frequency for wired and wireless communication simplifies the architecture of the interfaces located at the nodes.

The method of the invention maybe implemented in an existing wired system having a tree structure by configuring each node for wired and wireless transmission and reception of data signals at a frequency at which the effective isolation of each splitter in the system is 10-20 dB less than the specified in-band effective isolation of the splitter.

For a coax wired home networking system, in which coax lengths between nodes do not exceed 50 meters, it was found that frequencies that may be used to transmit AV signals over wireless networking systems may be used to transmit signals over a wired system in accordance with the invention. Examples of protocols for transmitting digital AV signals over a wireless system that may be used in accordance with the invention to transmit wired signals in a hybrid system of the invention include protocols 802.11a-e and Hiperlan-2 ([2] and [3]).

The method of the invention is preferably implemented in a wired system in which the guard time is sufficiently long so that essentially all reflections occur during the guard time, and the modulation scheme is capable of removing all reflections. The method of the invention is also preferably implemented in a wired system for which the cable infrastructure has acceptable loss at the frequency of the transmission. A wired system constructed as follows would have these features:

1. The coax cable attenuates less than 0.8 dB/meter. (The commonly used coaxial cables RG6U and RG59 have this characteristic).

2. The reflections from any point, up to 50 meters of coax length, exhibits less than 10dB variation in amplitude over 20 MHz RF bandwidth, with deeps not higher than 20 dB.

3. The effective delay for any reflection does not exceed 400 nSec. This would be the case when the cable length does not exceed 60 meters assuming an effective propagation speed of 0.5c within the coax. Thus, reflections from a 120 meter “round trip” along the coax will reach the source within 800 nSec, maximum.

A wired LAN (local access network) OFDM (Orthogonal Frequency Division Multiplex) physical layer (PHY) protocol has built-in features that enable the receiver to fight effectively against multi-path fading. A properly implemented equalizer in either 802.11a/g or HiperLan2 receiver can easily process channel amplitude variations of more than 25 dB and delay spreads of up to 800 nsec. In a typical coaxial cable, the above figures can be translated into a combined return loss of less than 1 dB and a maximum distance of 100 meters (assuming propagation speed inside the cable as half the speed of light in free space). This property of the OFDM PHY, also enables the system to operate properly even under severe multi-path conditions, such as multiple transmitters.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 shows a hybrid wired and wireless home networking system in which the coax and wireless are fully integrated, in accordance with one embodiment of the invention;

FIG. 2 shows an independent (coax-wireless) implementation of a node for the system shown in FIG. 1;

FIG. 3 shows a second structure for a node thin client for the system shown in FIG. 1 in which the physical layer sections are shared between the wireless and the coax;

FIG. 4 shows an implementation of the thin client transceiver for use in the systems shown in FIGS. 1 and 9, in accordance with the invention;

FIG. 5 shows a coax line amplifier repeater;

FIG. 6 shows a coax line amplifier/slitter;

FIG. 7 shows a tree configured coax infrastructure;

FIG. 8 shows a star configured coax infrastructure; and

### DETAILED DESCRIPTION OF THE INVENTION

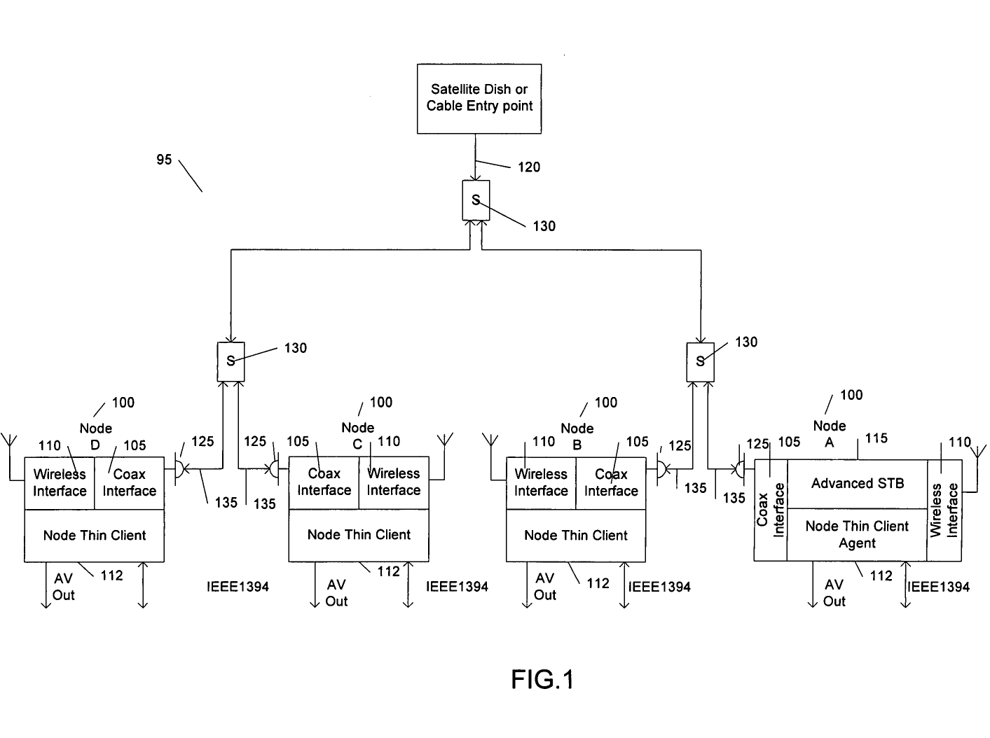

FIG. 1 shows a hybrid networking system, generally indicated as 95, in accordance with one embodiment of the invention. The system consists of a plurality of nodes 100. Each node has a node STB thin client 112 comprising wired interface 105 and a wireless interface 110. The system includes an advanced STB 115, that may be connected to an antenna such as a satellite dish, or a cable entry port. The wired subsystem has a “tree structure”, in which signals 120 received by the advanced STB 115 are subsequently split by one or more layers of signal splitters 130, until the signal has been split into a number of signals equal to the number of nodes 100. Two layers of splitters 130 are shown in FIG. 1, so that the initial signal 120 is ultimately split into four signals 135. The splitters shown in FIG. 1 are 1:2 splitters. (Each signal input to a splitter 130 is split into two signals.) This is by way of example only, and the system may include any number of generations of splitters and a splitter may split an input signal into any number of signals, as required in any application.

A satellite installation requires a wide band splitter. Each splitter has a nominal frequency and a specified isolation. In accordance with the invention, the nodes 100 are configured to transmit and receive wired and wireless data signals at the same frequency. A frequency is used at which the effective isolation of each splitter in the system is substantially less than the specified effective isolation of the splitter.

The signals 135 enter the coax interface 115 at wall sockets 125. The wall sockets are designed as 930 to 2500 MHz band pass filters combined with narrow pass-band near DC for a satellite installation, and are essentially simple low pass filters for a cable installation.

Each node STB outputs an output AV signal 140 that is input to evices such as a TV set, VCR etc. at the node (not shown).

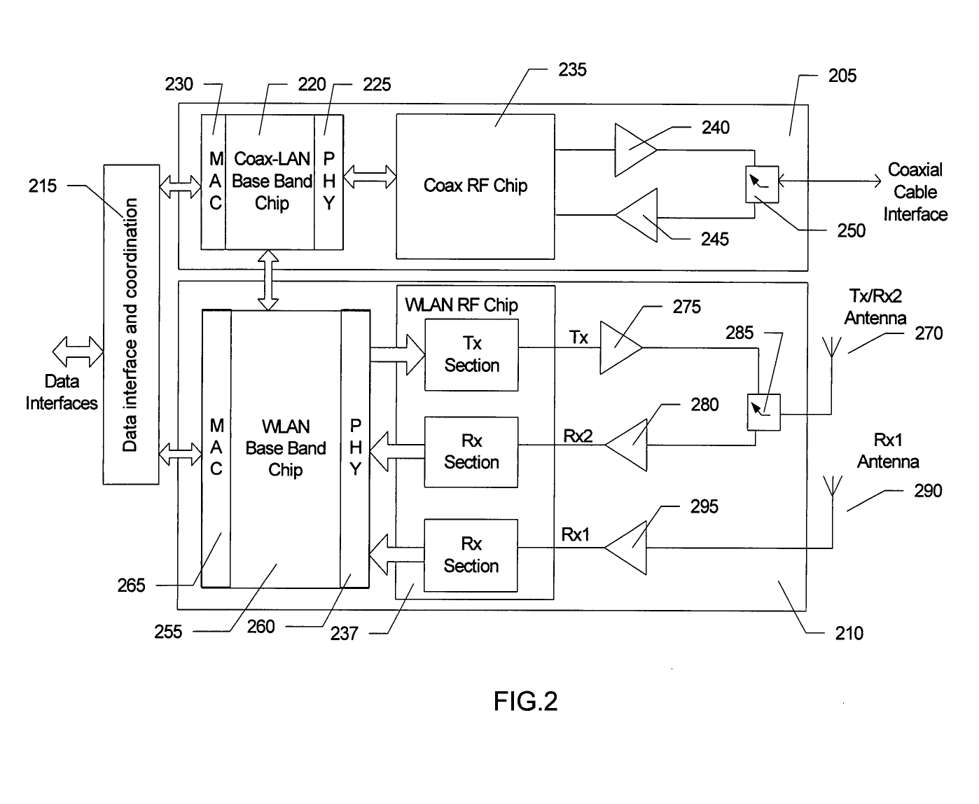

FIG. 2 shows an architecture, for a node STB 112 in accordance with one embodiment of the invention. This architecture includes a coax interface 205 and a wireless interface 210.

The coax interface 205 includes a coax LAN base band chip 220 that comprises a physical processor 225 and a MAC 230. The coax interface 205 also includes a coax RF chip 235, and input and output amplifiers 240 and 245, respectively.

The wireless interface 210 includes a wireless LAN base band chip 255 that comprises a PHY 260 and a media access control (MAC) 265. The wireless interface 210 also includes a wireless RF chip 237. A first antenna 270 is used for receiving and transmitting signals, via input amplifier 275 and output amplifier 280. The output amplifier 280 feed a switch 285 selecting the mode (transmission or receiving). A second antenna 290 is configured to receive signals that are amplified by an amplifier 295. The base band chips 220 and 255 interface with a data interface and coordinator 215.

In the architecture shown in FIG. 2, the wired and wireless subsystems interface at the base band chips 220 and 255. In this architecture, the system is an integration of two independent subsystems, each specially designed for the applicable media. The advantages of this architecture are:

[symbol] In The coaxial physical processor base band chip protocols can be designed as proprietary protocol, offering higher throughput, utilizing wider RF bandwidth and full duplex operation.

[symbol] Each system is optimized for the applicable media

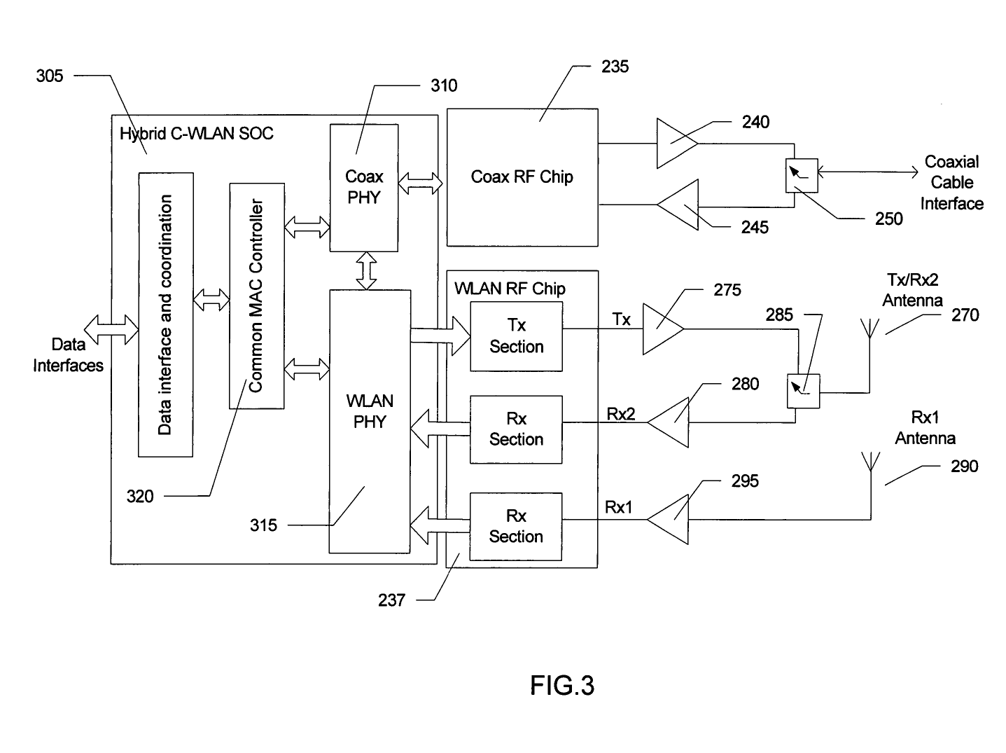

FIG. 3 shows another architecture for a node STB 112 in accordance with another embodiment of the invention. The architecture shown in FIG. 3 has several components in common with the architecture of FIG. 2, that are identified by the same numeral. The architecture of FIG. 3 includes a single system on a chip (SOC) 305, that comprises coax PHY 310, a wireless PHY 315, and a common MAC 320. The integration between the Coax and the Wireless is on the MAC level (i.e. the same MAC processor and the same protocol stack is used for both applications, while a different physical (PHY) processor is utilized).

The architecture shown in FIG. 3 has several advantages over the architecture shown in FIG. 2. First of all, a lower current consumption is possible by using the same firmware and software for both transceivers. There is also a lower cost due to the reduced circuitry. Moreover, there is a lower latency and shorter delays when transferring data to or from one link to the other

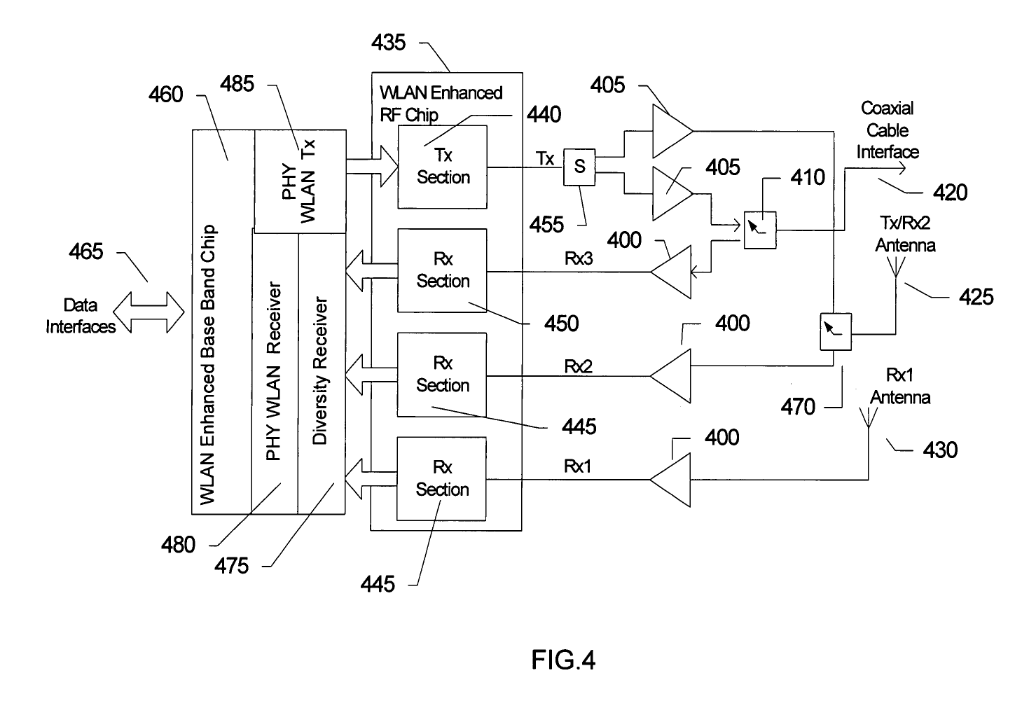

FIG. 4 shows another architecture for a node STB 112 in accordance with another embodiment of the invention. The architecture shown in FIG. 4 uses a fully integrated RF chip 435. On the transmit path, the wired and wireless subsystems share the same PHY transmitter 485. A power splitter 455 at the low level RF output from the RF chip provides the output power on both links in parallel. Each section uses its own power amplifier. The cable power amplifier output will feed a switch 410 selecting either Tx or Rx mode (WLAN protocol is TDM, half duplex, so that a unit is either transmitting or receiving in a given time period).

On the receive path the cable output is fed into a separate low noise amplifier 400 (LNA). The PHY receiver 480 utilizes triple space diversity reception 475, with two ports 445 received via the wireless section and the third one 450 is via the coax section. On the wireless section, one antenna 430 is dedicated for the receiver and the other is shared with the wireless transmitter 425. The coax Rx section 450, which provides the third diversity input. This configuration can be implemented in diversity selection-combining scheme 475, which can provide, under certain channel conditions, an improvement of up to 5 dB on link sensitivity over single antenna reception.

The embodiment of FIG. 4 has several advantages:

1. Minimum hardware—the same base band SOC and RF chip can be used for both Coax and Wireless media, leading to lower cost and current consumption.

2. No processing related interface between the Wireless and the coax media. The time delay between the two is virtually zero (up to differences in propagation delay)

3. The coax media and the wireless media can be received concurrently, providing up to 5 dB improved sensitivity (over conventional single antenna reception).

In most home wired installations, the existing coax infrastructure will suffice for carrying bi-directional high-speed data networking on 5 GHz RF band. However, since the wall sockets and the top-most splitter 130 (see FIG. 1) are the main causes of link losses, a wide band wall socket and/or a bi-directional cable repeater (splitter) and may be used to decrease the link losses. A side band wall socket contains an LC low-pass filter that assures the DC connectivity from the advanced STB to the satellite receiver and protects the advanced STB from spurious and other out-of-band interfering signals.

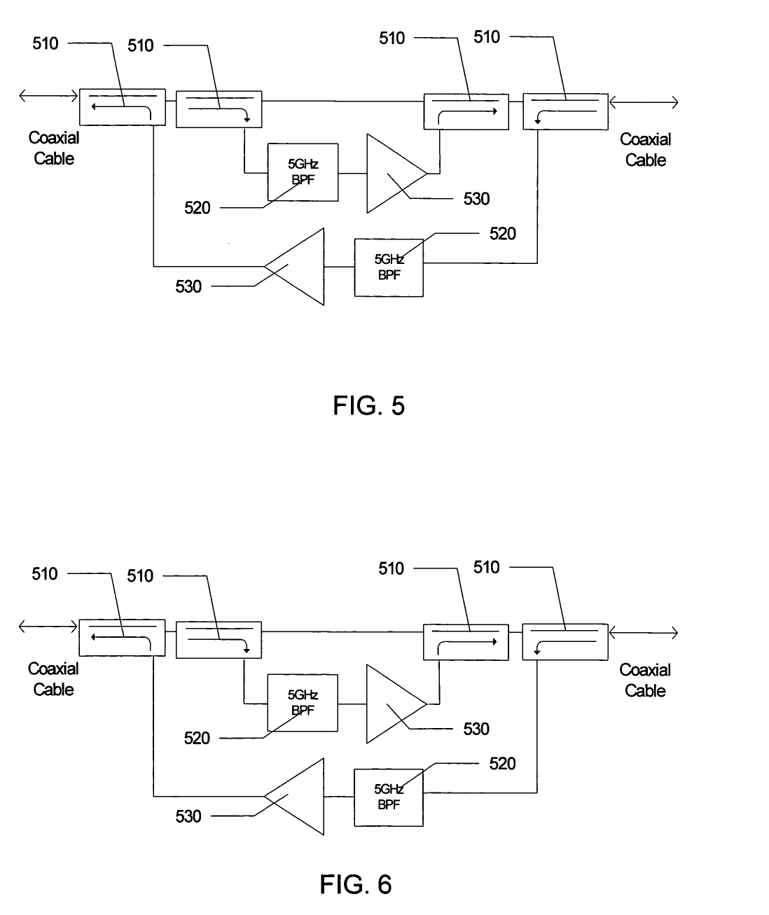

FIG. 5 shows a bi-directional repeater that can be used to increase the system range over the cable network. The directional couplers provide the necessary DC and RF isolation to eliminate loop back oscillations in the RF amplifiers. The amplifiers are designed to provide the required gain and are bias via a bias network, over the coaxial cable. A variation of the above cable repeater shown in FIG. 5 is the splitter-repeater shown in FIG. 6. It replaces the conventional Coax Splitter with an equivalent “low RF” splitter, bypassed by bi-directional repeater.

### EXAMPLE

Measurements of signal loss in a hybrid system of the invention at a transmission frequency of 5.7 GHz, show the following signal losses:

[symbol] Loss of RG6U cable at 5.7 GHz is about 0.6 dB/meter

[symbol] Connector losses at 5.7 GHz are about 0.5 dB per connector

[symbol] Loss of a typical 1:2 splitter, in-out, or out-in is between 5 to 15 dB

[symbol] Loss of a typical 1:2 splitter, out-out (isolation) is 6-12 dB

[symbol] Loss of a typical 1:4 splitter, out-out (isolation) is 15 dB

[symbol] Loss of a typical coax wall socket (satellite) is 12 dB (average)

[symbol] Loss of a typical wall socket (cable) is 5 dB

[symbol] Maximum peak-to-peak amplitude variation of a component, due to reflections at 5 GHz is 15 dB. Maximum peak-to-peak variation in 20 MHz RF bandwidth is 10 dB.

From the following table, based on 802.11a and HiperLan2 PHY specifications [2] and [3], we find that WLAN PHY requires a minimum of 65 dBm (802.11a) for proper detection of the maximum data rate (54 Mb/Sec) and the maximum available output power (for commercially available of-the-shelf RF power amplifier) is 23 dBm. Thus, the maximum allowed path loss for C-WLAN, via either coax or wireless is 88 dB.

| Data rate | 802.11a | |
|---|---|---|
| (Mb/Sec) | (dBm) | HL-2 (dBm) |
| 6 | −82 | −85 |
| 9 | −81 | −83 |
| 12 | −79 | −81 |
| 18 | −77 | −79 |
| 24 | −74 | x |
| 27 | x | −75 |
| 36 | −70 | −73 |
| 48 | −66 | X |
| 54 | −65 | −68 |

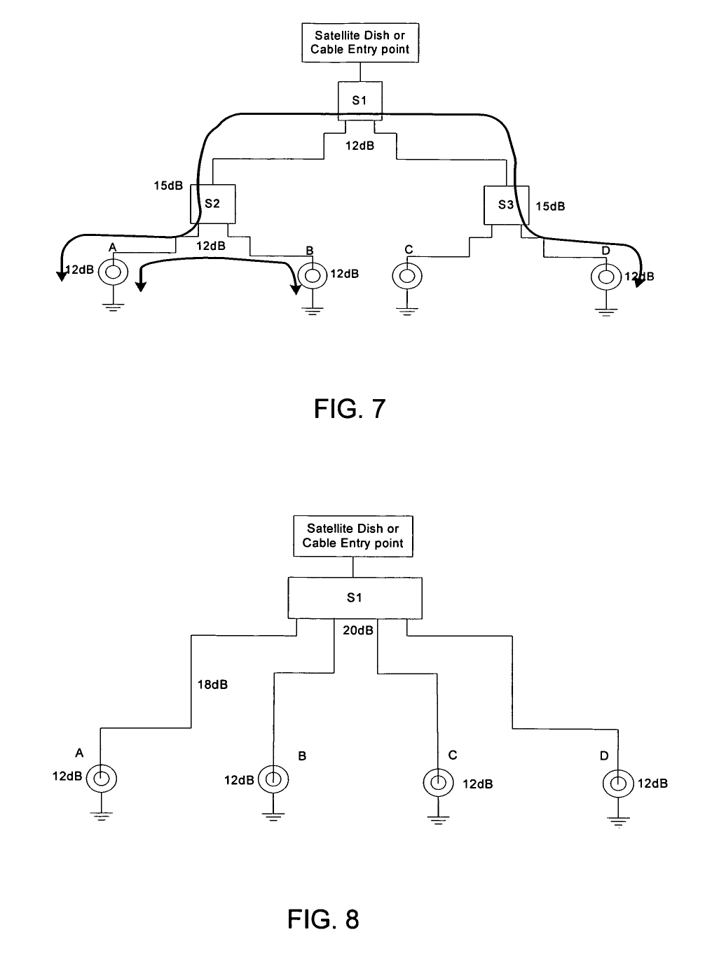

FIG. 7 shows a home networking installation, in which four nodes are serviced, and the coax distribution is a “tree” configuration. We assume that in satellite installations, since only one advanced STB is required, the wall sockets in each node are cable wall sockets which are cheaper and have lower loss.

The cable or satellite entry point feeds the system via splitter S1. There are four nodes serviced around the house: node A, B, C and D. Assuming that each coax section length is 10 meters, the loss over each coax section, including the connectors, is 10 dB. At each node, a C-WLAN terminal is connected. Consider the path from A to B. The total path loss is:

| | | |
|---|---|---|
| Wall Socket A | 12 | dB |
| Coax section to S2 | 10 | dB |
| Out-Out splitter S2 | 12 | dB |
| Coax section to wall socket B | 10 | dB |
| Wall Socket B | 12 | dB |
| Total Path loss | 56 | dB |
| Total signal at node B | −33 | dBm |

In the worst case, (which is apparently the connection between A or B to C or D):

| | | |
|---|---|---|
| Wall Socket A | 12 | dB |
| Coax section to S2 | 10 | dB |
| Out-In splitter S1 | 15 | dB |
| Coax section to S1 | 10 | dB |
| Out-Out splitter S1 | 12 | dB |
| Coax section to S3 | 10 | dB |
| In-Out splitter S3 | 15 | dB |
| Coax section to wall socket D | 10 | dB |
| Wall Socket D | 12 | dB |
| Total Path loss | 96 | dB |
| Total signal at node B | −73 | dBm |

Since the minimum required signal is −68 dBm, a repeater can be used to boost up the received power. The repeater should provide a minimum gain of 10 dB, on each direction. This can be easily achieved with conventional, low-cost, and simple RF design.

In the case of cable wall sockets, the same configuration is used as described above in reference to FIG. 7, with “regular”, lower loss wall sockets. Since the difference for each socket is 7 dB, the total path loss is 14 dB lower. Thus, in this case the path loss is 82 dB and the total signal level is −59 dBm.

Star Configuration

In a star configuration, as shown in FIG. 8, the system utilizes only one 1:4 splitter. All paths are equally weighted. Each coax section is 20 meters in length. The path loss from A to D (or to any other point in the house) can be calculated as follows:

| | | |
|---|---|---|
| Wall Socket A | 12 | dB |
| Coax section to S1 | 18 | dB |
| Out-Out splitter S1 | 20 | dB |
| Coax section to wall socket D | 18 | dB |
| Wall Socket B | 12 | dB |
| Total Path loss | 80 | dB |
| Total signal at node B | −57 | dBm |

### REFERENCES

[1] Maximizing Signal Strength Inside Buildings for Wireless LAN Systems Using OFDM. Eric Lawrey, C. J. Kikkert; James Cook University, Electrical and Computer Engineering, Townsville, Australia, 4814

[2] Supplement to IEEE Standard for Information technology—Telecommunications and information exchange between systems—Local and metropolitan area networks—Specific requirements—Part 11 Wireless LAN Medium Access Control (MAC) and Physical Layer (PHY) specifications: High-speed Physical Layer in the 5 GHZ Band

[3] ETSI TS 101 475 V1.2.1 (2000-11) Technical Specification; Broadband Radio Access Networks (BRAN); HIPERLAN Type 2; Physical (PHY) layer

1. A method for transmitting data signals between nodes in a networking system, the system comprising one or more signal splitters, each signal splitter having a nominal frequency and a specified effective isolation, the method comprising transmitting wired and wireless data signals between nodes at a same frequency, the effective isolation at the frequency being substantially less than the specified effective isolation of each splitter.

2. The method according to claim 1 wherein the frequency is a frequency specified by any one of the protocols 802.11a-e and Hiperlan-2.

3. A wired networking system comprising:
(One) one or more signal splitters each signal splitter having a nominal frequency and a specified effective isolation; and
(Two) two or more nodes, each node being configured to transmit and receive wired and wireless data signals over the system at the same frequency, the effective isolation at the frequency being less than the specified effective isolation of each splitter.

4. The system according to claim 3 wherein the frequency is a frequency specified by any one of the protocols 802.11a-e and Hiperlan-2.

5. A node set up box (STB) for use in the system of claim 1 or 2, comprising
(a) a coax interface having a LAN base chip;
(b) a wireless interface having a wireless base band chip;
wherein the STB is configured to transmit and receive wired and wireless AV signals at the same frequency, the effective isolation at the frequency being less than the specified effective isolation of each splitter in the system;
and wherein the coax LAN base band chip interfaces with the wireless LAN base band chip.

6. A node set up box (STB) for use in the system of claim 1 or 2, comprising a MAC processor, wherein the STB is configured to transmit and receive wired and wireless AV signals at the same frequency, the effective isolation at the frequency being less than the specified effective isolation of each splitter in the system; and wherein the same MAC processor and the same protocol stack are used for wired and wireless transmission.

7. A node set up box (STB) for use in the system of claim 1 or 2, comprising
(a) an RF chip for wired transmission, wired reception, wireless transmission and wireless reception; and
(b) a PHY transmitter for wired and wireless transmission;
wherein the STB is configured to transmit and receive wired and wireless AV signals at the same frequency, the effective isolation at the frequency being less than the specified effective isolation of each splitter in the system.

8. The node STB according to any one of the previous claims wherein the frequency is a frequency specified by any one of the protocols 802.11a-e and Hiperlan-2.
